(19) United States
(12) Patent Application Publication
(10) Pub. No.: US 2026/0068484 A1
(43) Pub. Date: Mar. 5, 2026

(54) DISPLAY DEVICE AND ELECTRONIC DEVICE

(71) Applicant: Samsung Display Co., Ltd., Yongin-Si (KR)

(72) Inventors: Hyun Sang SEO, Yongin-si (KR); Tae Kyu KIM, Yongin-si (KR); Ki Young YEON, Yongin-si (KR)

(21) Appl. No.: 19/062,019

(22) Filed: Feb. 25, 2025

(30) Foreign Application Priority Data
Aug. 27, 2024 (KR) 10-2024-0114768

(51) Int. Cl. H10K 59/80; H10K 59/40

(52) U.S. Cl. CPC H10K 59/872; H10K 59/40; H10K 59/8792; H10K 59/8793

(57) ABSTRACT

A display device includes a display panel, a window cover covering the display panel and including a recess that is concave in a vertical direction with respect to a top surface of the display panel, an outer frame combined with a lateral portion of the window cover, and a filling material interposed between the outer frame and the display panel to fill the recess.

### CROSS-REFERENCE TO RELATED APPLICATION AND CLAIM OF PRIORITY

This application claims priority to Korean Patent Application No. 10-2024-0114768 filed on Aug. 27, 2024, in the Korean Intellectual Property Office (KIPO), the entire disclosure of which is incorporated by reference herein.

### TECHNICAL FIELD

The disclosure of this patent application relates to a display device and an electronic device. More particularly, the disclosure of this patent application relates to a display device including a display panel and a window cover, and an electronic device including the same.

### BACKGROUND

In a display device such as an organic light emitting diode (OLED) display device and a liquid crystal display device (LCD), a display substrate including thin film transistors (TFTs) and various wirings is provided, and a display structure including electrodes and emission layers is formed on the display substrate to provide a display panel.

A window cover is attached to the display panel, and the display panel and the window cover may be fixed to an outer frame by a filling material. However, the display panel may be detached due to an external impact applied to the display device, or defects such as lift-off and peel-off of structures included in the display panel may occur.

### SUMMARY

According to an aspect of the present disclosure, there is provided a display device having improved mechanical and structural reliability.

According to an aspect of the present disclosure, there is provided an electronic device having improved mechanical and structural reliability.

A display device may include a display panel, a window cover covering the display panel and including a recess that is concave in a vertical direction with respect to a top surface of the display panel, an outer frame combined with a lateral portion of the window cover, and a filling material interposed between the outer frame and the display panel to fill the recess.

In some embodiments, the display device may further include a light-shielding layer formed on a bottom surface of the window cover. The filling material may contact the light-shielding layer and side surfaces of the recess.

In some embodiments, the light-shielding layer may include a first light-shielding layer formed on a ceiling of the recess and a second light-shielding layer formed on a portion of the bottom surface of the window cover around the recess.

In some embodiments, the first light-shielding layer and the second light-shielding layer may be separated or spaced from each other by the side surfaces of the recess.

In some embodiments, the first light-shielding layer and the second light-shielding layer may be arranged alternately and repeatedly along a horizontal direction.

In some embodiments, the recess may include a first recess portion and a second recess portion having different widths. The second recess portion may be formed at an entrance of the recess, and the first recess portion may have a shape expanding horizontally from the second recess portion.

In some embodiments, the filling material may include a second filling portion formed in the second recess portion and a first filling portion formed in the first recess portion which includes expanded portions expanding horizontally from the second filling portion.

In some embodiments, the window cover may include a protrusion protruding in the horizontal direction in the second recess portion and the second recess portion may have a bottleneck shape defined by the protrusion.

In some embodiments, the display device may further include a light-shielding layer formed on a bottom surface of the window cover. The light-shielding layer may be partially formed on a ceiling of the recess.

In some embodiments, the window cover may include protrusions defining the recess, and the filling material may include filling portions formed between adjacent protrusions of the protrusions.

In some embodiments, each of the protrusions may include a curved surface.

In some embodiments, the recess may include an intermediate region having a relatively reduced width.

In some embodiments, each of the protrusions may have a trapezoidal shape.

In some embodiments, the display device may further include a touch sensor layer and a polarizing layer stacked between the window cover and the display panel. The filling material may cover lateral surfaces of the display panel, the touch sensor layer and the polarizing layer.

A display device includes a display panel, a window cover covering the display panel, an outer frame combined with to a lateral portion of the window cover, a filling material filling a space between the outer frame and the display panel, and a blocking structure disposed between the filling material and the display panel.

In some embodiments, the blocking structure and the filling material may include a resin material, and an elastic modulus of the blocking structure may be greater than an elastic modulus of the filling material.

In some embodiments, the blocking structure may contact the filling material and may be disposed on a lateral surface of the display panel.

In some embodiments, the display device may further include a rear cover supporting a rear surface of the display panel. The blocking structure may be inserted between a lateral portion of the rear cover and the display panel.

In some embodiments, the display device may further include a touch sensor layer and a polarizing layer stacked between the window cover and the display panel. The blocking structure may commonly cover lateral surfaces of the touch sensor layer and the polarizing layer.

In some embodiments, the window cover may include a recess and the filling material may include a filling portion filling the recess.

An electronic device may include the above-described display device, a memory, and a processor configured to execute data included in the memory to control an operation of the display device.

In some embodiments, the electronic device may include virtual or augmented reality glasses, a smartphone, a tablet PC, a laptop, a TV, a desk monitor, smart glasses, a head mounted display, a smart watches, or a vehicle display.

In a display device according to embodiments of the present inventive concept, a recess may be formed at a lower portion of a window cover and a filling material may be formed to be contact with the recess. An impact-mitigating portion may be formed by a portion of the filling material filling the recess. The impact-mitigating portion may block or reduce a stress transmitted to the window cover and a display panel, thereby preventing mechanical instability such as detachment/film lift-off of the display panel.

In some embodiments, a surface of the recess may include a portion on which a light-shielding layer is formed and a portion on which a light-shielding layer is not formed, and the filling material may have increased adhesive strength by the portion on which the light-shielding layer is not formed.

### BRIEF DESCRIPTION OF THE DRAWINGS

FIG. 1 is a schematic exploded perspective view illustrating a display device or an electronic device in accordance with example embodiments.

FIGS. 2 and 3 is a schematic plan view and a schematic cross-sectional view of a display panel in accordance with example embodiments.

FIG. 4 is a partially enlarged cross-sectional view schematically illustrating a display device in accordance with some embodiments.

FIG. 5 is a partially enlarged cross-sectional view schematically illustrating an impact-mitigating portion of a display device in accordance with some embodiments.

FIG. 6 is a partially enlarged cross-sectional view schematically illustrating a display device in accordance with example embodiments.

FIG. 7 is a partially enlarged cross-sectional view schematically illustrating an impact-mitigating portion of a display device in accordance with some embodiments.

FIG. 8 is a partially enlarged cross-sectional view schematically illustrating an impact-mitigating portion of a display device in accordance with some embodiments.

FIG. 9 is a partially enlarged cross-sectional view schematically illustrating an impact-mitigating portion of a display device in accordance with some embodiments.

FIG. 10 is a partially enlarged cross-sectional view schematically illustrating an impact-mitigating portion of a display device in accordance with some embodiments.

FIG. 11 is a partially enlarged cross-sectional view schematically illustrating a display device in accordance with some embodiments.

FIG. 12 is a partially enlarged cross-sectional view schematically illustrating a display device in accordance with some embodiments.

FIG. 13 is a block diagram of an electronic device in accordance with an embodiment.

FIG. 14 is a schematic diagram of electronic devices in accordance with various embodiments.

### DETAILED DESCRIPTION OF THE EMBODIMENTS

Hereinafter, embodiments of the present inventive concept will be described in more detail with reference to the attached drawings. The same reference numerals can be used for indicating the same elements in the drawings, and repeated descriptions of the same elements can be omitted. Embodiments disclosed in the attached drawings are exemplary, and is to be understood to include all modifications, equivalents and substitutes included in the spirit and technical scope of the present inventive concept.

The terms “on”, “connected”, “coupled,” etc., used herein refers to a direct placement/connection/combination, and also refers to a case where another element is interposed two different elements.

The terms such as “first”, “second”, “below”, “below”, “above,” “above,” etc., are used in a relative sense to distinguish different elements or positions, and do not specify an absolute position or an absolute order.

In the present disclosure, “upper surface (or upper portion)” and “lower surface (or lower portion)” may be distinguished based on a direction from a rear cover RC to a window cover WC.

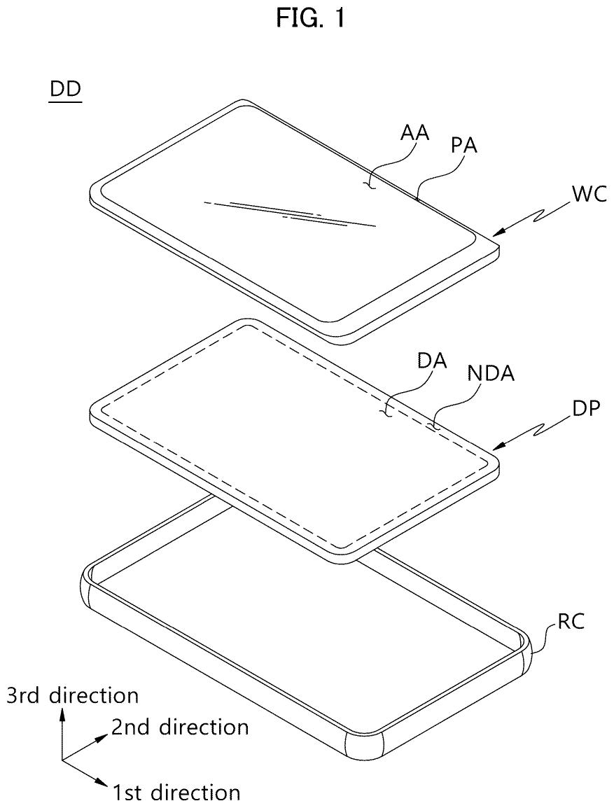

FIG. 1 is a schematic exploded perspective view illustrating a display device or an electronic device in accordance with example embodiments.

In FIG. 1, a first direction and a second direction may refer to two directions parallel to a display surface of the window cover WC and/or a display panel DP, and orthogonal to each other. For example, the first direction may correspond to an X-direction (a row direction) of a display device DD or the display panel DP, and the second direction may correspond to a Y-direction (a column direction) of the display device DD or the display panel DP.

A third direction may be perpendicular to the first direction and the second direction. The third direction may correspond to a Z-direction (a thickness direction) of the display device DD or the display panel DP.

In the accompanying drawings, the definition of the direction described above may be equally applied.

Referring to FIG. 1, a display device DD or an electronic device may include the window cover WC, the display panel DP and a rear cover RC. The rear cover RC, the display panel DP, and the window cover WC may be sequentially stacked in the third direction.

The display device DD may include a liquid crystal display (LCD) device, an organic light emitting diode (OLED) display, a quantum dot light emitting diode (QLED) display, etc. In example embodiments, the display device DD may be an OLED display device including an organic emission layer. For example, the display device DD may be implemented in the form of a mobile phone (smart phone), a tablet, a PC, or the like.

The window cover WC may provide an external display surface recognized by a user such as a visible surface of a mobile phone and may include a transparent film. For example, the window cover WC may include glass (e.g., ultra-thin glass UTG), a hard coating film, a plastic film, etc.

An outer surface of the window cover WC may include an active area AA and a peripheral area PA. The active area AA may provide a surface from which an image of the display device is substantially displayed and to which a user's touch/command is input. The peripheral area PA may substantially correspond to a bezel area, a black matrix area, or the like, of the display device DD. The active area AA may be an area overlapping the display panel DP in the third direction. The peripheral area PA may be a margin area that may not overlap the display panel DP in the third direction.

The display panel DP may include a display area DA and a non-display area NDA.

For example, a sensor structure for touch sensing or fingerprint sensing may be disposed within the display panel DP between the window cover WC and the display panel DP. An optical functional layer such as a polarizing plate may be stacked between the window cover WC and the display panel DP.

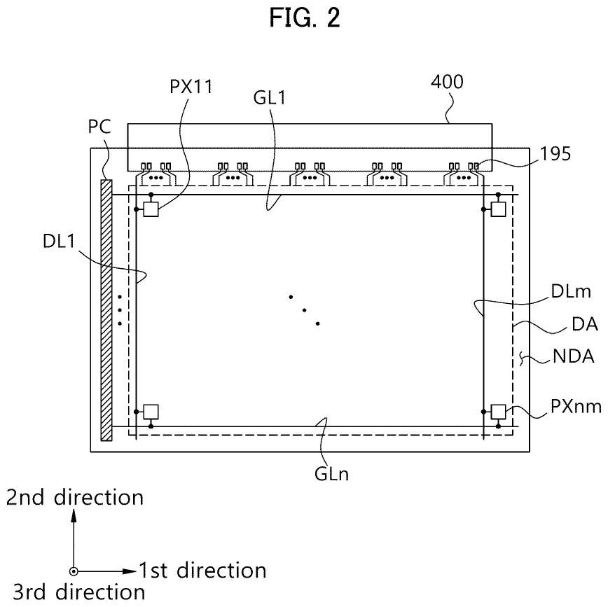

The rear cover RC may serve as a rear frame or a rear housing of the display device DD or the electronic device. A cover panel may be disposed between the rear cover RC and the display panel DP. The rear cover RC or the cover panel may include a plate (e.g., an SUS plate) supporting the display panel DP. A printed circuit board 400 (see FIG. 2), or the like, may be disposed between the display panel DP and the rear cover RC. The rear cover RC may include an elastic body for absorbing a shock from an outside of the display device DD or the electronic device.

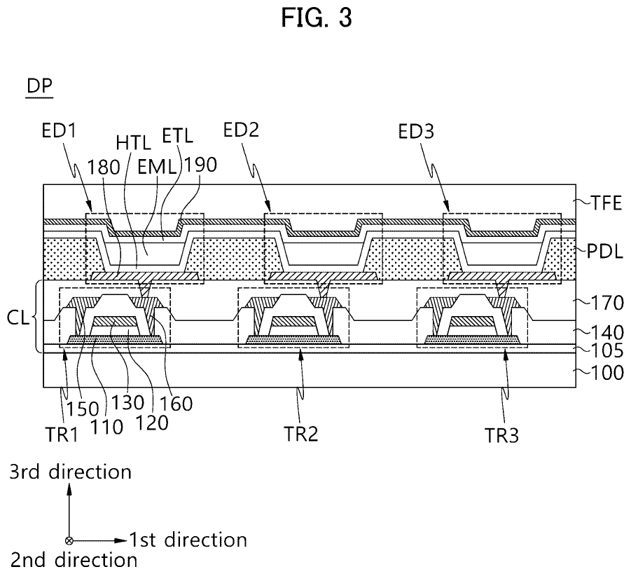

FIGS. 2 and 3 is a schematic plan view and a schematic cross-sectional view of a display panel in accordance with example embodiments.

Referring to FIG. 2, a plurality of pixels PX11 to PXnm may be arranged in the display area DA of the display panel DP.

In example embodiments, a pixel circuit including scan lines (or gate lines) GL1 to GLn forming first to nth rows and data lines DL1 to DLm forming first to mth columns may be arranged on a base substrate 100 of the display panel DP. Each of the pixels PX11 to PXnm may be connected to a corresponding nth row scan line among a plurality of scan lines GL1 to GLn and a corresponding mth column data line among a plurality of data lines DL1 to DLm.

Each of the pixels PX11 to PXnm may further include a pixel driving/switching device including a transistor and a light-emitting device as will be described below. Although not illustrated in detail in FIG. 3, the pixel circuit may further include wirings such as a power line, a ground line, etc.

FIG. 2 illustrates that the data lines DL1 to DLm extend in the second direction and the scan lines GL1 to GLn extend in the first direction, but the construction of the data lines and the gate lines is not limited to that illustrated in FIG. 2.

A peripheral circuit PC may be disposed in the non-display area NDA of the display panel DP. For example, the peripheral circuit PC may include a gate driving circuit. The gate driving circuit may be integrated into the display panel DP by an oxide silicon gate (OSG) driver circuit or an amorphous silicon gate (ASG) driver circuit process.

The display device DD may further include a printed circuit board 400. Pads 195 of the pixel circuit may be disposed at one end portion of the non-display area NDA. The printed circuit board 400 may be electrically connected to the pixel circuit through the pads 195. For example, the printed circuit board 400 may be electrically connected to the pads 195 by a heating-compression process using a conductive intermediate structure such as an anisotropic conductive film ACF.

An integrated circuit IC such as a data driving circuit may be disposed on the printed circuit board 400. In some embodiments, an integrated circuit IC chip in the form of a chip-on-film (COF) may be mounted on the printed circuit board 400.

Referring to FIG. 3, the display panel DP may include the base substrate 100, a circuit layer CL stacked on the base substrate 100, and a light-emitting device disposed on the circuit layer CL.

The base substrate 100 may serve as a supporting substrate or a back-plane substrate of the display device. A glass substrate or a plastic substrate may be used as the base substrate 100.

In some embodiments, the base substrate 100 may include a polymer material having transparency and flexibility. In this case, the display panel DP may be used in a transparent flexible display device. For example, the base substrate 100 may include a polymer material such as polyimide, polysiloxane, an epoxy resin, an acrylic resin, polyester, or the like. In an embodiment, the base substrate 100 may include polyimide.

The circuit layer CL may include transistors TR1, TR2, and TR3. The circuit layer CL may include wiring layers and insulating layers forming a thin film transistor array TFT-Array.

The circuit layer CL may further include a buffer layer 105 formed on a top surface of the base substrate 100. Moisture penetrating through the base substrate 100 may be blocked by the buffer layer 105, and diffusion of impurities from the base substrate 100 and under the base substrate 100 to a structure formed on the base substrate 100 may be blocked by the buffer layer 105.

The buffer layer 105 may include, e.g., an inorganic insulating material such as silicon oxide, silicon nitride, silicon oxynitride, or the like. These may be used alone or in a combination of two or more therefrom. In some embodiments, the buffer layer 105 may have a stacked structure including a silicon oxide layer and a silicon nitride layer.

The buffer layer 105 may be formed by a deposition process such as a chemical vapor deposition (CVD) process, a sputtering process, or an atomic layer deposition (ALD) process to include the inorganic insulating material.

The transistors TR1, TR2 and TR3 may be disposed on the buffer layer 105. The first transistor TR1, the second transistor TR2 and the third transistor TR3 may be electrically connected to a first light-emitting device ED1, a second light-emitting device ED2 and a third light-emitting device ED3, respectively.

Each of the transistors TR1, TR2 and TR3 may include an active layer 110, a gate insulation layer 120, a gate electrode 130, and connection electrodes 150 and 160.

The active layer 110 may be disposed on the buffer layer 105 and may be patterned by, e.g., a photo-lithography process to be repeatedly/regularly arranged at each pixel. The active layer 110 may include a silicon compound such as polysilicon or amorphous silicon. A p-type dopant or an n-type dopant may be doped in a partial region of the active layer 110 and may include a source region, a drain region and a channel region.

The active layer 110 may include an oxide semiconductor such as indium gallium zinc oxide (IGZO), zinc tin oxide (ZTO) or ITZO.

The gate insulation layer 120 may be formed on the active layer 110 and the gate electrode 130 may be stacked on the gate insulation layer 120. As illustrated in FIG. 3, the gate insulation layer 120 may be formed in a pattern shape partially covering each active layer 110. Alternatively, the gate insulation layer 120 may extend continuously over a plurality of the pixels or light-emitting regions, and may be commonly included in the first to third transistors TR1, TR2 and TR3.

The gate electrode 130 may overlap the channel region of the active layer 110 in the third direction.

The gate insulation layer 120 may be formed by the above-described deposition process to include an inorganic insulating material such as silicon oxide, silicon nitride, silicon oxynitride, or the like. In some embodiments, the gate insulation layer 120 having a patterned shape may be formed as illustrated in FIG. 2 by a photo-lithography process using the gate electrode 130 substantially as an etching mask.

In some embodiments, the gate electrode 130 and the gate insulation layer 120 may be used as a self-aligned ion implantation mask to form the source region and the drain region in the active layer 110.

An insulating interlayer 140 covering the gate insulation layer 120 and the gate electrode 130 may be formed on the active layer 110. The connection electrodes 150 and 160 which may be in contact with or electrically connected to the active layer 110 may be formed on the insulating interlayer 140.

The insulating interlayer 140 may be formed by the above-described deposition process to include an inorganic insulating material such as silicon oxide, silicon nitride, and/or silicon oxynitride. The insulating interlayer 140 may be formed in a single-layered structure or a multi-layered structure including different materials.

In some embodiments, if the active layer 110 includes an oxide semiconductor, hydrogen (H) contained in the insulating interlayer 140 may be diffused or moved to the active layer 110 by a heat treatment process when forming the insulating interlayer 140. Accordingly, a carrier concentration may be increased by hydrogen, and thus the source region and the drain region having increased conductivity may be formed at lateral portions of the active layer 110.

The connection electrodes 150 and 160 may penetrate the insulating interlayer 140 and may be connected to the active layer 110. When the gate insulation layer 120 is continuously formed commonly in a plurality of pixel regions, the connection electrodes 150 and 160 may also penetrate the gate insulation layer 120.

The connection electrodes 150 and 160 may include a source electrode 150 connected to or in contact with the source region of the active layer 110 and a drain electrode 160 connected to or in contact with the drain region of the active layer 110.

Contact holes may be formed by partially removing the insulating interlayer 140. For example, the contact hole may be formed in an area corresponding to each of the source region and the drain region. A metal layer sufficiently filling the contact holes may be formed on the insulating interlayer 140 and the metal layer may be patterned to form the source electrode 150 and the drain electrode 160.

The gate electrode 130 and the connection electrodes 150 and 160 may include a metal such as Ag, Mg, Al, W, Cu, Ni, Cr, Mo, Ti, Pt, Ta, Nd, Sc, an alloy thereof, and/or a nitride thereof. The gate electrode 130 and the connection electrodes 150 and 160 may be formed by the above-described deposition process.

A planarization layer 170 covering the connection electrodes 150 and 160 may be formed on the insulating interlayer 140. A via structure electrically connecting a pixel electrode 180 and the drain electrode 160 may be formed in the planarization layer 170 may include a via hole.

In some embodiments, the planarization layer 170 may include an organic material such as polyimide, an epoxy resin, an acrylic resin, polyester, a siloxane resin, a benzocyclobutene (BCB), or the like. The planarization layer 170 may be formed by the above-described deposition process or a spin coating process.

A pixel electrode 180 may be formed in each pixel to be electrically connected to the transistors TR1, TR2 and TR3 through the via structure formed in the planarization layer 170. The pixel electrode 180 may be formed on the planarization layer 170 to be electrically connected to the drain electrode 160 through the via hole formed in the planarization layer 170.

For example, the planarization layer 170 may be partially removed to form a via hole formed in an area corresponding to a top surface of the drain electrode 160. A conductive layer including a metal or a transparent conductive oxide and sufficiently filling the via hole may be formed on a top surface of the planarization layer 170, and then the conductive layer may be patterned to form the pixel electrode 180.

The pixel electrode 180 may serve as an anode and may include a high work function conductive material to promote a hole injection. The pixel electrode 180 may serve as a transmissive electrode. The pixel electrode 180 may include a transparent conductive oxide such as indium tin oxide (ITO), indium zinc oxide (IZO), zinc oxide (ZnO) and/or indium tin oxide (ITZO).

The pixel electrode 180 may serve as a transflective electrode or a reflective electrode. The pixel electrode 180 may include a metal selected from a group consisting of Ag, Mg, Cu, Al, Pt, Pd, Au, Ni, Nd, Ir, Cr, Li, Ca, LiF, Mo, Ti, W, In, Sn and Zn, or an alloy of two or more therefrom.

The pixel electrode 180 may have a single-layered structure or a multi-layered structure. For example, the pixel electrode 180 may have a triple-layered structure of ITO/Ag/ITO.

A pixel defining layer PDL, a light-emitting portion, and a counter electrode 190 may be disposed on the circuit layer CL. Each of the light-emitting devices ED1, ED2 and ED3 may include the pixel electrode 180, the light-emitting portion and the counter electrode 190.

The pixel defining layer PDL may be formed on the planarization layer 170 to cover edges of a top surface of the pixel electrode 180. A light-emitting region may be defined by a sidewall of the pixel defining layer PDL. A red light-emitting region, a green light-emitting region and a blue light-emitting region may be separated and defined by the pixel defining layer PDL, and the light emitting devices ED1, ED2 and ED3 may include a red light-emitting device, a green light-emitting device and a blue light-emitting device, respectively.

In some embodiments, all of the light emitting device ED1, ED2 and ED3 may be white light-emitting devices or blue light-emitting devices.

The light-emitting portion may be disposed in each light-emitting region formed by the pixel defining layer PDL. In example embodiments, the light-emitting portion may include an emission layer EML including an organic light-emitting material. For example, the emission layer EML may include a fluorescent host and/or a phosphorescent host, and may further include a fluorescent dopant, a phosphorescent dopant, and/or a thermally activated delayed fluorescent (TADF) dopant.

For example, the light-emitting portion may be formed by a process such as a vacuum deposition, a spin coating, an inkjet printing, a laser printing, a casting, a laser thermal transfer, or the like.

The counter electrode 190 may be disposed on top surfaces of the pixel defining layer PDL and the light emitting-portions. The counter electrode 190 may be a common electrode that is continuously provided commonly in a plurality of the light emitting-regions or the pixels.

The counter electrode 190 may serve as an electron injection electrode or a cathode. The counter electrode 190 may include a metal, an alloy, an electrically conductive compound, or the like, having a low work function.

For example, the counter electrode 190 may include lithium (Li), silver (Ag), magnesium (Mg), aluminum (Al), aluminum-lithium (Al—Li), calcium (Ca), magnesium-indium (Mg—In), magnesium-silver (Mg—Ag), ytterbium (Yb), silver-ytterbium (Ag—Yb), ITO, IZO, or the like. These may be used alone or in combination of two or more therefrom.

The counter electrode 190 may be provided as a transmissive electrode, a transflective electrode, or a reflective electrode. The counter electrode 190 may have a single-layered structure or a multi-layered structure.

The light-emitting portion may further include a hole transport layer (HTL) and an electron transport layer (ETL). In example embodiments, the hole transport layer HTL, the emission layer EML, the electron transport layer ETL and the counter electrode 190 may be sequentially stacked from the top surface of the pixel electrode 180.

For example, the hole transport layer HTL may include a hole transport material such as m-MTDATA (4,4′,4″-[tris(3-methylphenyl)phenylamino] triphenylamine), TDATA (4,4′4″-tris(N,N-diphenylamino)triphenylamine), 2-TNATA (4,4′,4″-tris[N(2-naphthyl)-N-phenylamino]-triphenylamine), NPB (N,N′-di(naphthalene-1-yl)-N,N′-diphenyl-benzidine), TPD (N,N′-bis(3-methylphenyl)-N,N′-diphenyl-[1,1′-biphenyl]-4,4′-diamine), TCTA (4,4′,4″-tris(N-carbazolyl)triphenylamine), PEDOT/PSS (poly(3,4-ethylenedioxythiophene)/poly(4-styrenesulfonate)), or the like.

For example, the electron transport layer (ETL) may include an electron transport material such as an anthracene-based compound, Alq3 (tris(8-hydroxyquinolinato)aluminum), TPBi (1,3,5-Tri(1-phenyl-1H-benzo[d]imidazol-2-yl)benzene), BCP (2,9-dimethyl-4,7-diphenyl-1,10-phenanthroline), Bphen(4,7-diphenyl-1,10-phenanthroline), TAZ (3-(4-biphenylyl)-4-phenyl-5-tert-butylphenyl-1,2,4-triazole), NTAZ (4-(naphthalen)-1-yl)-3,5-diphenyl-4H-1,2,4-triazole), tBu-PBD (2-(4-biphenylyl)-5-(4-tert-butylphenyl)-1,3,4-oxadiazole), BAlq (bis(2-methyl-8-quinolinolato-N1,O8)-(1,1′-biphenyl-4-olato)aluminum), or the like.

In some embodiments, a hole injection layer may be further formed between the pixel electrode 180 and the hole transport layer HTL. An electron injection layer may be further formed between the counter electrode 190 and the electron transport layer ETL.

In some embodiments, the layers included in the above-described light-emitting portion may be patterned within the light-emitting region defined by the pixel definition layer PDL similarly to the emission EML illustrated in FIG. 3. Accordingly, the light-emitting portions may be separated from each other in the form of an island in each of a plurality of the pixels.

In some embodiments, the layers included in the above-described light-emitting portion may continuously and commonly extend throughout a plurality of the pixels and the top surfaces of the pixel defining layer PDL.

An encapsulation layer TFE may be formed on the display panel DP to cover the light-emitting devices ED1, ED2 and ED3. In an embodiment, the encapsulation layer TFE may be included as an element of the display panel DP.

The encapsulation layer TFE may include an inorganic layer including silicon nitride (SiNx), silicon oxide (SiOx), indium tin oxide, indium zinc oxide, or any combination thereof; an organic layer including polyethylene terephthalate, polyethylene naphthalate, polycarbonate, polyimide, polyethylene sulfonate, polyoxymethylene, polyarylate, hexamethyldisiloxane, an acrylic resin (e.g., polymethylmethacrylate, polyacrylic acid, etc.), an epoxy resin (e.g., aliphatic glycidyl ether (AGE)) or any combination thereof; or a combination of the inorganic and organic layers.

The encapsulation layer TFE may be formed in a single-layered or a multi-layered structure. In some embodiments, the encapsulation layer TFE may have a first inorganic layer, an organic layer and a second inorganic layer sequential stacked on the light-emitting devices ED1, ED and ED3.

In some embodiments, the display panel DP may further include a color control structure disposed on the light-emitting devices ED1, ED and ED3. The color control structure may include a color filter corresponding to each of the light-emitting devices ED1, ED2 and ED3, or each pixel.

The color filter may selectively transmit a light of a specific wavelength band, and may substantially absorb a remaining light. Accordingly, reflection of an external light may be decreased while enhancing a color purity of the display device DD.

The color filter may include, e.g., a first color filter that transmits a blue light having a central wavelength ranging from 420 nm to 480 nm, a second color filter that transmits a green light having a central wavelength ranging from 500 nm to 580 nm, and a third color filter that transmits a red light having a central wavelength ranging from 600 nm to 670 nm.

The first to third color filters may correspond to the first to third light-emitting devices ED1, ED2 and ED3, respectively.

The color control structure may include a color conversion portion including, e.g., quantum dots between the color filter and the light-emitting device. In this case, the display device DD may be provided as a QD-OLED device. For example, a color of an emitted light may be adjusted according to a particle size of the quantum dots. The quantum dots may be classified into blue quantum dots, red quantum dots and green quantum dots.

The color conversion portion may include a first color conversion layer, a second color conversion layer and a third color conversion layer corresponding to the first light emitting device ED1, the second light emitting device ED2 and the third light emitting device ED3, respectively, to overlap in the third direction.

In example embodiments, a blue light having a central wavelength in a range of, e.g., 420 nm to 480 nm may be generated from the light-emitting portion. The first color conversion layer corresponding to the first light-emitting device ED1 may transmit the blue light. In this case, the color conversion layer may not include quantum dots and may include a scattering material. The scattering material may include TiO₂, ZnO, Al₂O₃, SiO₂, hollow silica, or the like. These may be used alone or in a combination of two or more therefrom.

The second color conversion layer corresponding to the second light-emitting device ED2 may convert the blue light into the green light having a central wavelength in a range of, e.g., 500 nm to 580 nm.

The third color conversion layer corresponding to the third light-emitting device ED3 may convert the blue light into the red light having a center wavelength in a range of, e.g., 600 nm to 670 nm.

In some embodiments, the first to third light emitting devices ED1, ED2 and ED3 may be light-emitting devices having a tandem structure that may commonly emit a white light. In this case, the first to third light emitting devices ED1, ED2 and ED3 may be stacked in the third direction for each pixel or light-emitting region defined by the pixel defining layer PDL with a charge generation layer interposed therebetween.

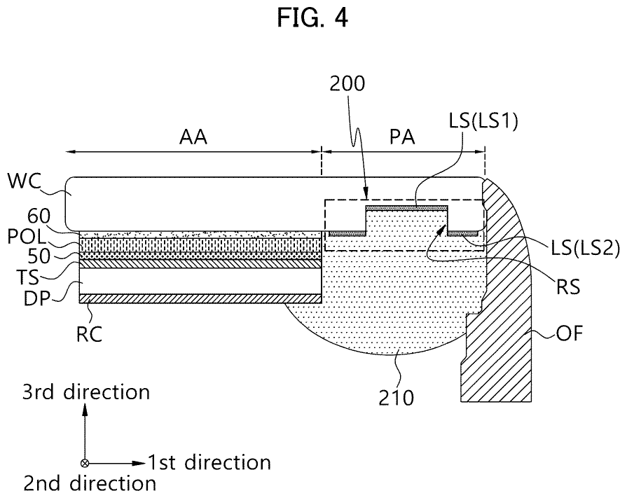

FIG. 4 is a partially enlarged cross-sectional view schematically illustrating a display device in accordance with some embodiments. FIG. 4 illustrates a portion of the display device DD at a boundary between the peripheral area PA and the active area AA of the window cover WC. For convenience of descriptions, FIG. 4 may be a cross-sectional view that illustrates the window cover WC, an outer frame OF and a filling material 210 in the peripheral area PA in enlarged or exaggerated sizes.

Referring to FIG. 4, as described above, the active area AA of the window cover WC may substantially cover the display panel DP, and may overlap the display panel DP in the third direction. In some embodiments, the active area AA of the window cover WC may completely cover the display panel DP.

As described with reference to FIG. 1, a rear surface of the display panel DP may be supported by the rear cover RC. A touch sensor layer TS and/or a polarizing layer POL may be further stacked on the display panel DP. In some embodiments, the touch sensor layer TS, the polarizing layer POL and the window cover WC may be sequentially stacked from an upper surface of the display panel DP (e.g., an upper surface of the encapsulation layer TFE).

In some embodiments, the touch sensor layer TS may be included in the form of a module including a touch sensor substrate and a sensing electrode layer formed on a top surface of the touch sensor substrate. In this case, an adhesive layer may be formed between a bottom surface of the touch sensor substrate and the encapsulation layer TFE to attach the module-shaped touch sensor layer TS to the encapsulation layer TFE.

In some embodiments, the touch sensor substrate may be omitted. In this case, the sensing electrode layer may be included in an on-cell type layer directly deposited and patterned on the encapsulation layer TFE.

The touch sensor layer TS and the polarizing layer POL may be coupled or attached to each other by an adhesive layer 50. The polarizing layer POL may be disposed on the touch sensor layer TS to efficiently suppress or reduce reflection of an external light caused by the sensing electrode layer.

In some embodiments, the polarizing layer POL may be provided in the form of a polarizing plate including a polarizer and a protective film formed on upper and/or lower surfaces of the polarizer. The polarizer may include an iodine-dyed polyvinyl alcohol (PVA) film. The polarizer may be stretched in a specific axial direction to provide polarization properties by oriented iodine molecules.

The polarizing layer POL may be attached to a bottom surface of the window cover WC by a second adhesive layer 60.

The first and second adhesive layers 50 and 60 may include an adhesive material such as an optically clear adhesive (OCA), an optically clear resin (OCR), or the like. The term “adhesive layer” used herein may also cover a pressure-sensitive adhesive layer.

A lateral portion of the window cover WC may be coupled to the outer frame OF, and thus an outer portion of the display device DD may be entirely fixed by the outer frame OF. For convenience of descriptions, only a lateral portion of the outer frame OF is briefly illustrated in FIG. 4, and a bottom portion of the outer frame OF may be coupled to the rear cover RC such that a rear portion of the display device DD may also be fixed.

The peripheral area PA of the window cover WC may serve as a bezel portion or a light-shielding portion. The outer frame OF and the display panel DP may be spaced apart from each other by a predetermined distance in the first direction in the peripheral area PA.

The filling material 210 may fill a space between the display panel DP and the outer frame OF, and may protect and fix a lateral surface of the display panel DP. The filling material 210 may also fill a space between the touch sensor layer TS and the outer frame OF, and a space between the polarizing layer POL and the outer frame OF.

The outer frame OF may include a metallic material such as steel use stainless (SUS) or a ceramic material having a high rigidity. The filling material 210 may include a thermosetting or photocurable resin such as an acrylic resin, a silicone resin, an ester resin, an epoxy resin, or the like.

In an embodiment, the above-described resin material may be filled in a space between the display panel DP and the outer frame OF, and then may be cured. In an embodiment, the filling material 210 may be formed on the bottom surface of the window cover WC and the lateral surface of the display panel DP by an injection molding using the resin material. Thereafter, the outer frame OF may be coupled to the lateral portion of the window cover WC by using the filling material 210.

According to embodiments of the present inventive concept, a portion of the window cover WC in the peripheral area PA may include a recess RS. For example, the window cover WC of the peripheral area PA may be partially removed by an etchant such as hydrofluoric acid to form the recess RS that may be concave in a direction from the bottom surface to a top surface of the window cover WC.

The filling material 210 may fill the recess RS. In example embodiments, the recess RS may be substantially and completely filled with the filling material 210.

A light-shielding layer LS may be formed on a bottom surface of a portion of the window cover WC in the peripheral area PA. The light-shielding layer LS may be formed by coating or spraying a light-shielding composition including a binder resin and a colorant material such as a black colorant material on the bottom surface of the portion of the window cover WC in the peripheral area PA.

The light-shielding layer LS may be formed discontinuously on the bottom surface of the peripheral area PA. In example embodiments, a sidewall of the recess RS may include a portion not covered by the light-shielding layer LS. In an embodiment, the light-shielding layer LS may not be substantially formed on the sidewall of the recess RS.

Accordingly, the light-shielding layer LS may include a first light-shielding layer LS1 formed on a ceiling of the recess RS or a bottom surface of the window cover WC in the recess RS, and a second light-shielding layer LS2 formed on the bottom surface of the window cover WC in the peripheral area PA at an outside of the recess RS.

The filling material 210 may commonly contact the first light-shielding layer LS1 of the light-shielding layer LS and the second light-shielding layer LS2 of the light-shielding layer LS, and may be in contact with the sidewall of the recess RS.

In some embodiments, the filling material 210 may also contact the lateral surface of the display panel DP and an inner surface of the outer frame OF. In an embodiment, the filling material 210 may also contact a lateral surface of the touch sensor layer TS and/or the polarizing layer POL.

According to embodiments of the present disclosure as described above, the filling material 210 may be included as a reinforcing material filling the space between the display panel DP and the outer frame OF. As described above, the filling material 210 may include the resin material having an elasticity, and may protect the display panel DP from a horizontal stress applied to the display device DD and transferred from the outer frame OF to the display panel DP. Additionally, moisture penetration into the display panel DP may be blocked or reduced by the filling material 210.

Even when a reinforcing material is included between the display panel DP and the outer frame OF, the reinforcing material may be peeled off by a vertical stress from the top surface of the window cover WC to an inside of the display device DD. When the reinforcing material is peeled off from the window cover WC, layers included in the display panel DP, the touch sensor layer TS and/or the polarizing layer POL may also be peeled off or detached together with the reinforcing material.

Further, an adhesion between the reinforcing material and the light-shielding layer LS may be relatively weak, and the peel-off of the reinforcing material may be more easily caused.

However, according to embodiments of the present inventive concept, the recess RS that may be concave in the third direction (the vertical direction) may be formed in the window cover WC, and the filling material 210 may be coupled to the recess RS. Accordingly, a bonding area of the filling material 210 may be increased, and the peel-off/detachment of the filling material 210 and the display panel DP due to the vertical stress may be prevented.

Additionally, the filling material 210 may be in contact with the exposed sidewall of the recess RS by discontinuously forming the light-shielding layer LS. The filling material 210 may be in contact with light-shielding layer LS and the surface of the window cover WC in the recess RS to increase adhesion of the filling material 210. Therefore, separation of the filling material 210 due to the vertical stress may be more effectively prevented.

As indicated by a dotted square in FIG. 4, an impact-mitigating portion 200 may be defined by the recess RS and portions of the window cover WC and the filling material 210 around the recess RS. As described above, the peel-off of the filling material 210 due to the vertical stress may be suppressed by the structure of the impact-mitigating portion 200. Further, stresses introduced from different directions may be offset by the structure of the recess RS of the impact-mitigating portion 200.

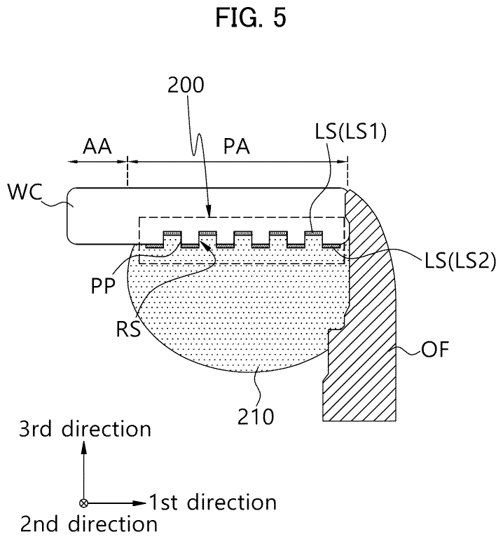

FIG. 5 is a partially enlarged cross-sectional view schematically illustrating an impact-mitigating portion of a display device in accordance with some embodiments.

Referring to FIG. 5, a plurality of recesses RS may be formed in the window cover WC of the peripheral area PA. Accordingly, the window cover WC may have a substantially sawtooth shape or a wavy shape in the peripheral area PA.

As the recesses RS are repeated, the impact-mitigating portion 200 may include a plurality of protrusions PP protruding in a direction from the top surface to the bottom surface of the window cover WC in the peripheral area PA. The filling material 210 may fill the recesses RS and cover the protrusions PP.

The light-shielding layer LS may include a first light-shielding layer LS1 formed on a ceiling of each recess RS and a second light-shielding layer LS2 formed on a surface of the protrusion PP. In the cross-section of FIG. 5, a plurality of the first light-shielding layers LS1 and the second light-shielding layers LS2 may be alternately repeated.

As described above, the impact-mitigating portion 200 may include a unit coupling structure of a plurality of the recesses RS/the filling material 210, and may more effectively implement stress dispersion/offset while preventing the peel-off of the filling material 210.

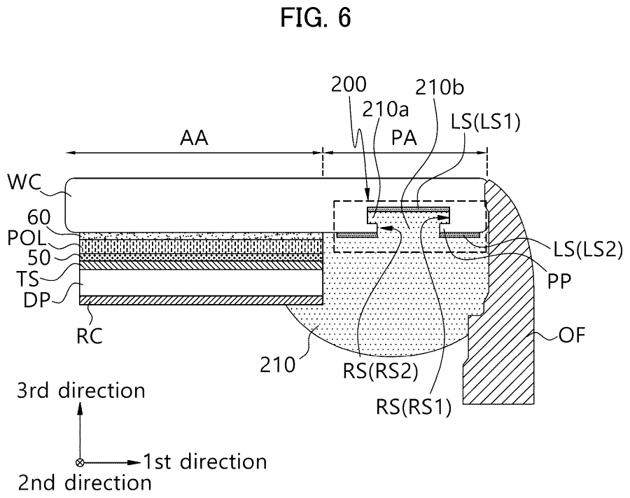

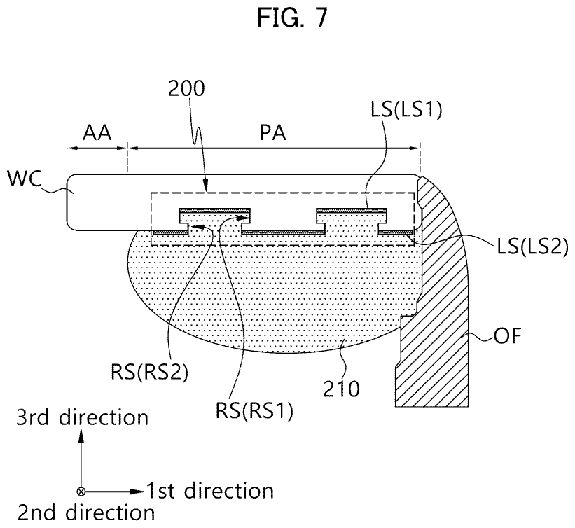

FIG. 6 is a partially enlarged cross-sectional view schematically illustrating a display device in accordance with example embodiments. FIG. 7 is a partially enlarged cross-sectional view schematically illustrating an impact-mitigating portion of a display device in accordance with some embodiments. Detailed descriptions of elements, structures and material substantially the same as or similar to those described with reference to FIGS. 4 and 5 are omitted.

Referring to FIG. 6, the recess RS may include portions having different widths. In example embodiments, the recess RS may include a second recess portion RS2 substantially corresponding to a recess inlet and a first recess portion RS1 having a width increased from the second recess portion RS2. The first recess portion RS1 and the second recess portion RS2 may be integrally formed to be provided as a single or unitary recess RS.

The second recess portion RS2 may be defined by a protrusion PP of the window cover WC. In the cross-section of FIG. 6, the second recess portion RS2 may be defined by a pair of the protrusions PP protruding in the horizontal direction (the first direction) in the cross-sectional view.

The second recess portion RS2 may substantially have a bottle-neck shape. The first recess portion RS1 may have an expanded portion shape. Accordingly, a contact area between the sidewall of the recess RS and the filling material 210 may be increased.

In the impact-mitigating portion 200, the filling material 210 may include a first filling portion 210a formed in the first recess portion RS1 and a second filling portion 210b formed in the second recess portion RS2. The first filling portion 210a may be integrally connected to the second filling portion 210b, and may have a shape expanding in the horizontal direction from an upper portion of the second filling portion 210b.

The first light-shielding layer LS1 may be formed on a ceiling of the first recess portion RS1, and the light-shielding layer LS may be at least partially not formed on the sidewall of the recess RS. Accordingly, the first filling portion 210a and the second filling portion 210b may be in contact with the sidewall of the recess RS.

The impact-mitigating portion 200 may substantially have a hook structure by the above-described recess RS shape. Thus, the peel-off due to vertical stress of the filling material 210 may be more effectively suppressed. For example, the protrusion PP of the window cover WC may serve as a blocking structure for suppressing the peel-off of the filling material 210.

Referring to FIG. 7, the window cover WC may include a plurality of the recesses RS, and each of the recesses RS may include the first recess portion RS1 and the second recess portion RS2 as described with reference to FIG. 6. Accordingly, a unit structure having the hook structure as described above in the impact-mitigating portion 200 may be repeated in the first direction.

Thus, dispersion/offset of stress and stability of the filling material 210 may be more effectively implemented throughout the entire peripheral area PA.

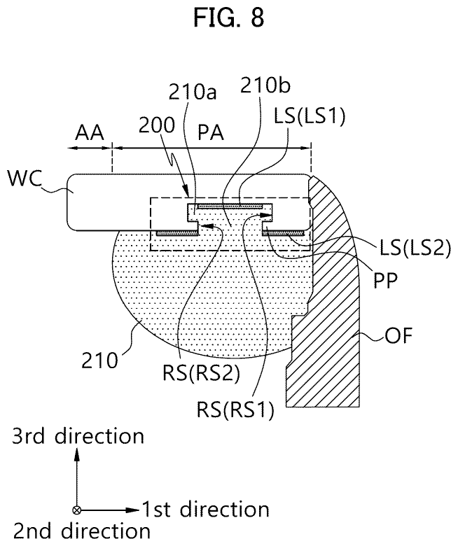

FIG. 8 is a partially enlarged cross-sectional view schematically illustrating an impact-mitigating portion of a display device in accordance with some embodiments. Detailed descriptions of elements and structures substantially the same as or similar to those described with reference to FIGS. 6 and 7 are omitted.

Referring to FIG. 8, the first light-shielding layer LS1 formed on the ceiling of the first recess portion RS1 of the light-shielding layer LS may partially cover the ceiling of the first recess portion RS1.

In some embodiments, the first light-shielding layer LS1 may not be formed on a portion of the ceiling of the first recess portion RS1 covered by the protrusion PP in the third direction. In some embodiments, the first light-shielding layer LS1 may be selectively formed on a portion of the ceiling of the first recess portion RS1 exposed by the second recess portion RS2 in the third direction.

The first filling portion 210a filling the first recess portion RS1 may be in contact with the first light-shielding layer LS1 and the ceiling of the first recess portion RS1. Accordingly, adhesion of the first filling portion 210a to the window cover WC may be further increased, and the peel-off of the filling material 210 due to the vertical stress may be additionally suppressed.

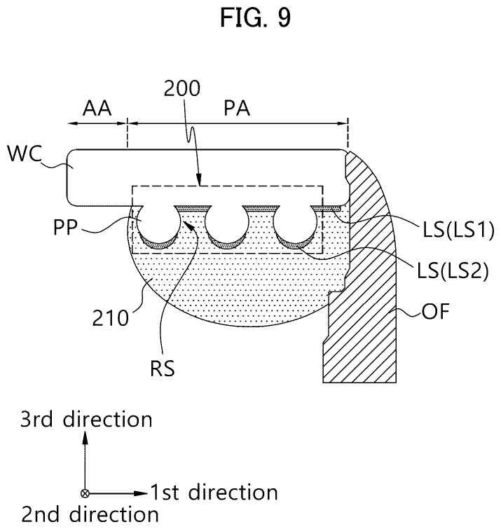

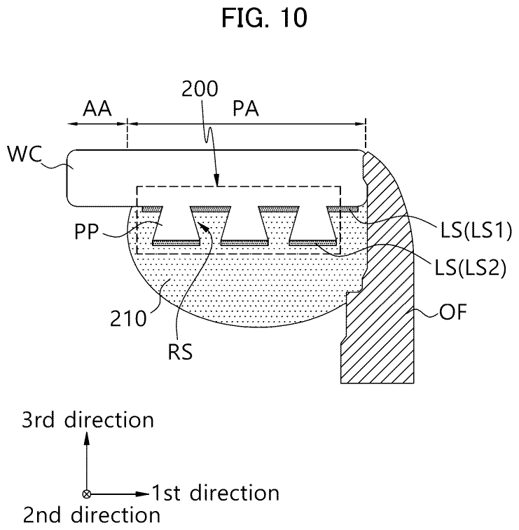

FIGS. 9 and 10 are partially enlarged cross-sectional views schematically illustrating impact-mitigating portions of a display device in accordance with some embodiments. Detailed descriptions of the configuration and structure substantially the same as or similar to those described with reference to FIGS. 4 and 5 are omitted.

Referring to FIG. 9, the protrusion PP of the window cover WC may include a curved surface. For example, the protrusion PP may have a circular or elliptical shape in a cross-sectional view.

A recess RS may be defined between protrusions PP adjacent to each other in the first direction, and a sidewall of the recess RS may have a convex curved shape. Accordingly, a filling portion defined by the filling material 210 filling the recess RS may include an intermediate region having a relatively narrow width, and may include an expanded portion having a width greater than that of the intermediate region. Accordingly, the impact-mitigating portion 200 may include a substantially hook structure.

The light-shielding layer LS includes a first light-shielding layer LS1 formed on a ceiling of the recess RS and a second light-shielding layer LS2 formed on a bottom of the protrusion PP, and the first light-shielding layer LS1 and the second light-shielding layer LS2 may be separated or spaced apart from each other with the sidewall of the recess RS interposed therebetween.

The second light-shielding layer LS2 may have a substantially curved shape along a circumference of the protrusion PP. In example embodiments, a plurality of the protrusions PP may be arranged along the first direction, and the second light-shielding layer LS2 and the first light-shielding layer LS1 may be alternately and repeatedly arranged along the first direction.

Referring to FIG. 10, the protrusion PP may have a substantially trapezoidal shape in a cross-sectional view. For example, a width of the protrusion portion PP may gradually decrease along the third direction (a direction from the bottom surface of the window cover WC to the top surface). The recess RS may be defined between the protrusions PP adjacent to each other in the first direction. The recess RS may have a substantially inverted trapezoidal shape.

A width of the recess RS may gradually increase along the third direction. Accordingly, the filling portion including the filling material 210 that fills the recess RS may have an expanded upper portion, and the impact-mitigating 200 may substantially include a hook structure.

A sidewall of the recess RS may have an inclined shape. The first light-shielding layer LS1 and the second light-shielding layer LS2 may be spaced apart from each other with the sidewall of the recess RS interposed therebetween, and may be alternately and repeatedly arranged.

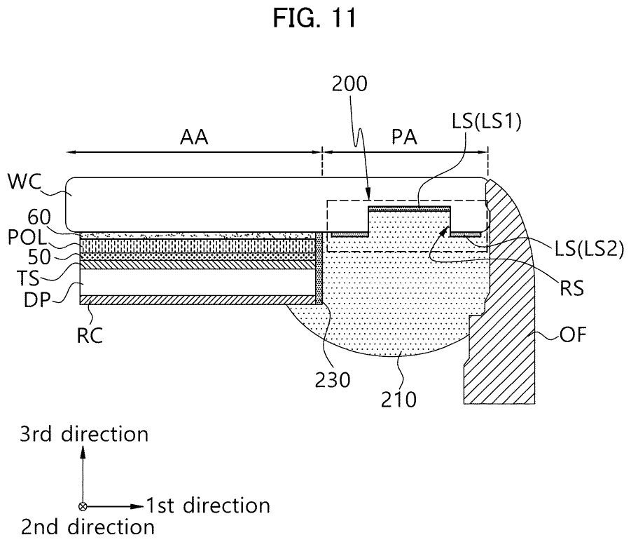

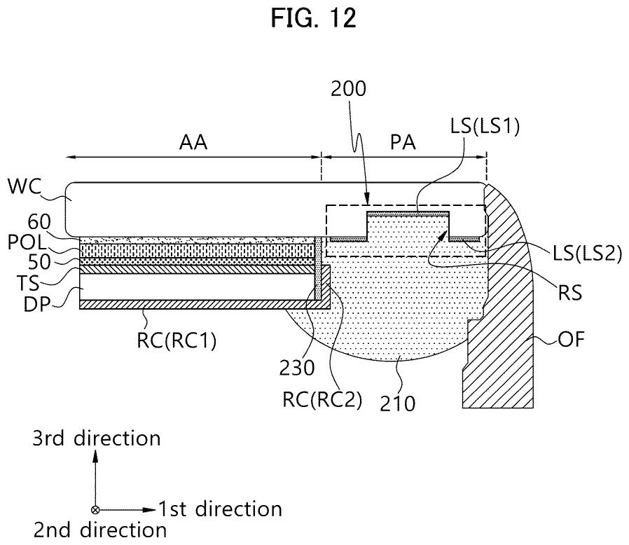

FIG. 11 is a partially enlarged cross-sectional view schematically illustrating a display device in accordance with some embodiments. FIG. 12 is a partially enlarged cross-sectional view schematically illustrating a display device in accordance with some embodiments. Detailed descriptions of elements and materials substantially the same as or similar to those described with reference to FIGS. 4 and 5 are omitted.

Referring to FIG. 11, the display device DD may further include a blocking structure 230 disposed between the filling material 210 and the display panel DP. The blocking structure 230 may include a urethane-based resin, a polyethylene-based resin, an acrylic-based resin, or the like.

In some embodiments, the blocking structure 230 may have an elastic modulus (modulus) or a tensile strength higher than that of the filling material 210. Thus, a stress transmitted in the horizontal direction (e.g., the first direction) by passing through the filling material 210 may be effectively blocked. Thus, damages to the display panel DP due to the stress transmitted directly from the outer frame OF may be prevented.

The blocking structure 230 may be formed on the lateral surface of the display panel DP. The blocking structure 230 may also extend on the lateral surface of the touch sensor layer TS and/or the polarizing layer POL. In some embodiments, the blocking structure 230 may contact the bottom surface of the window cover WC.

For example, in a state that the blocking structure 230 is attached to the lateral surfaces of the display panel DP, the touch sensor layer TS and the polarizing layer POL, the above-described resin material may be injected to form the filling material 210. The blocking structure 230 may be in direct contact with the filling material 210 and may block the stress transmitted from the filling material 210 to the display panel DP, the touch sensor layer TS and the polarizing layer POL.

In an embodiment, an adhesive layer may be disposed between the blocking structure 230 and the display panel DP.

Referring to FIG. 12, the blocking structure 230 may be inserted between the display panel DP and the rear cover RC.

The rear cover RC may include a first portion RC1 supporting a rear surface or a bottom surface of the display panel DP, and a second portion RC2 at least partially surrounding the lateral surface of the display panel DP. The first portion RC1 may correspond to a main body of the rear cover RC, and the second portion RC2 may have a shape bent from the first portion RC1.

The blocking structure 230 may be disposed between the lateral surface of the display panel DP and the second portion RC2 of the rear cover RC. Accordingly, the blocking structure 230 may be supported by the rear cover RC. Thus, the blocking structure 230 may be prevented from being separated by the stress transmitted through the filling material 210, and the blocking structure 230 may be stably maintained on the lateral surface of the display panel DP.

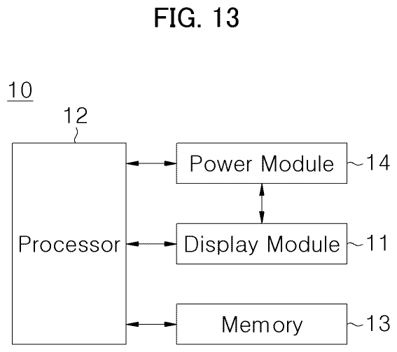

FIG. 13 is a block diagram of an electronic device in accordance with an embodiment.

Referring to FIG. 13, an electronic device 10 according to an embodiment may include a display module 11, a processor 12, a memory 13 and a power module 14.

The processor 12 may include a central processing unit (CPU), an application processor (AP), a graphic processing unit (GPU), a communication processor (CP), an image signal processor (ISP) and/or a controller.

Data information for an operation of the processor 12 or the display module 11 may be stored in the memory 13. When the processor 12 executes an application stored in the memory 13, an image data signal and/or an input control signal may be transmitted to the display module 11, and the display module 11 may process the received signal and output image information through a display screen.

The power module 14 may include a power supply module such as a power adapter or a battery device, and a power conversion module that converts a power supplied by the power supply module to a generate power required for the operation of the electronic device 10.

At least one of components of the electronic device 10 as described above may be included in the display device according to the above-described embodiments. Additionally, some of individual modules functionally included in one module may be included in the display device, and others may be provided separately from the display device. For example, the display module 11 may include the display device, and the processor 12, the memory 13 and the power module 14 may be provided in the form of another device in the electronic device 10 different from the display device.

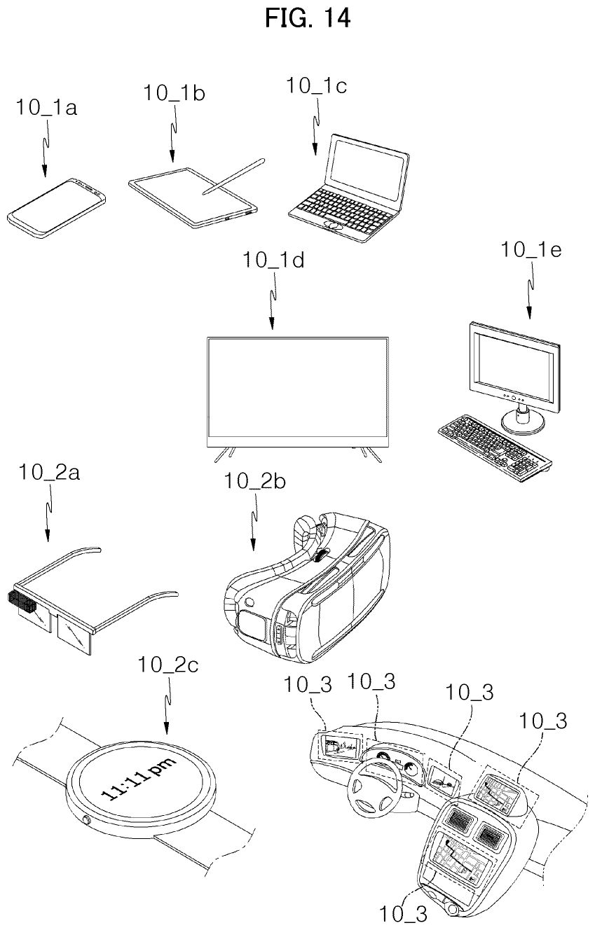

FIG. 14 is a schematic diagram of electronic devices in accordance with various embodiments.

Referring to FIG. 14, non-limiting examples of various electronic devices to which the display device according to the above-described embodiments is applied include an electronic device for displaying an image such as a smartphone 10_1a, a tablet PC 10_1b, a laptop 10_1c, a TV 10_1d, a desk monitor 10_1e, and/or the like; a wearable electronic device including a display module such as smart glasses 10_2a, a head mounted display 10_2b, a smart watch 10_2c, and/or the like; a vehicle electronic device 10_3 including a display module such as a center information display (CID) disposed at a vehicle instrument panel, a center fascia, a dashboard, etc., a room mirror display, and/or the like. The electronic device may include a virtual reality glass or an augmented reality glass.

What is claimed is:

1. A display device, comprising:
a display panel;
a window cover covering the display panel and including a recess that is concave in a vertical direction with respect to a top surface of the display panel;
an outer frame combined with a lateral portion of the window cover, and
a filling material interposed between the outer frame and the display panel to fill the recess.

2. The display device of claim 1, further comprising a light-shielding layer formed on a bottom surface of the window cover,
wherein the filling material contacts the light-shielding layer and side surfaces of the recess.

3. The display device of claim 2, wherein the light-shielding layer comprises a first light-shielding layer formed on a ceiling of the recess and a second light-shielding layer formed on a portion of the bottom surface of the window cover around the recess.

4. The display device of claim 3, wherein the first light-shielding layer and the second light-shielding layer are separated or spaced from each other by the side surfaces of the recess.

5. The display device of claim 4, wherein the first light-shielding layer and the second light-shielding layer are arranged alternately and repeatedly along a horizontal direction.

6. The display device of claim 1, wherein the recess includes a first recess portion and a second recess portion having different widths, and
wherein the second recess portion is formed at an entrance of the recess, and the first recess portion has a shape expanding horizontally from the second recess portion.

7. The display device of claim 6, wherein the filling material includes a second filling portion formed in the second recess portion and a first filling portion formed in the first recess portion which includes expanded portions expanding horizontally from the second filling portion.

8. The display device of claim 6, wherein the window cover includes a protrusion protruding in the horizontal direction in the second recess portion and the second recess portion has a bottleneck shape defined by the protrusion.

9. The display device of claim 6, further comprising a light-shielding layer formed on a bottom surface of the window cover,
wherein the light-shielding layer is partially formed on a ceiling of the recess.

10. The display device of claim 1, wherein the window cover includes protrusions defining the recess, and the filling material includes filling portions formed between adjacent protrusions of the protrusions.

11. The display device of claim 10, wherein each of the protrusions includes a curved surface.

12. The display device of claim 1, further comprising a touch sensor layer and a polarizing layer stacked between the window cover and the display panel,
wherein the filling material covers lateral surfaces of the display panel, the touch sensor layer and the polarizing layer.

13. A display device, comprising
a display panel;
a window cover covering the display panel;
an outer frame combined with to a lateral portion of the window cover;
a filling material filling a space between the outer frame and the display panel; and
a blocking structure disposed between the filling material and the display panel.

14. The display device of claim 13, wherein the blocking structure and the filling material include a resin material, and an elastic modulus of the blocking structure is greater than an elastic modulus of the filling material.

15. The display device of claim 13, wherein the blocking structure contacts the filling material and is disposed on a lateral surface of the display panel.

16. The display device of claim 13, further comprising a rear cover supporting a rear surface of the display panel,
wherein the blocking structure is inserted between a lateral portion of the rear cover and the display panel.

17. The display device of claim 13, further comprising a touch sensor layer and a polarizing layer stacked between the window cover and the display panel,
wherein the blocking structure commonly covers lateral surfaces of the touch sensor layer and the polarizing layer.

18. The display device of claim 13, wherein the window cover includes a recess and the filling material includes a filling portion filling the recess.

19. An electronic device, comprising:
a display device;
a memory; and
a processor configured to execute data included in the memory to control an operation of the display device,
wherein the display device comprises:
a display panel;
a window cover covering the display panel and including a recess that is concave in a vertical direction with respect to a top surface of the display panel;
an outer frame combined with a lateral portion of the window cover; and
a filling material interposed between the outer frame and the display panel to fill the recess.

20. The electronic device of claim 19, wherein the electronic device includes virtual or augmented reality glasses, a smartphone, a tablet PC, a laptop, a TV, a desk monitor, smart glasses, a head mounted display, a smart watches, or a vehicle display.
